(19) United States
(12) Patent Application Publication
(10) Pub. No.: US 2013/0250990 A1
(43) Pub. Date: Sep. 26, 2013

(54) LASER EMITTING CHIP PACKAGE

(71) Applicant: KAI-WEN WU, Tu-Cheng (TW)

(72) Inventor: KAI-WEN WU, Tu-Cheng (TW)

(21) Appl. No.: 13/631,697

(22) Filed: Sep. 28, 2012

(30) Foreign Application Priority Data
Mar. 26, 2012 (TW) 101110326

(51) Int. Cl. H01S 5/02

(52) U.S. Cl. 372/44.01

(57) ABSTRACT

A laser emitting chip package includes a circuit board, a laser emitting chip, and at least three gold balls. The circuit board includes at least two substrate-pad areas. The laser emitting chip includes at least two chip-pad areas. Each of the chip-pad areas spatially corresponds to a respective one of the substrate-pad areas. The at least three gold balls are explanted on the at least two chip-pad areas. The laser emitting chip is supported on the circuit board by the at least three gold balls in a triangular or square arrangement between the chip-pad areas and the substrate-pad areas. The laser emitting chip is electrically connected to the circuit board through the gold balls.

### BACKGROUND

1. Technical Field

The present disclosure relates to package structures and, particularly, to a laser emitting chip package.

2. Description of Related Art

With the development of the optical communication technology, Vertical Cavity Surface-Emitting Lasers (VCSEL) are widely used in a variety of optical communication devices. In related art, the VCSEL includes a laser emitting chip, a circuit board, and other electronic components. The laser emitting chip is electrically connected to and supported on the circuit board using flip-chip package method. For example, explanting a gold ball on a chip-pad area of the laser emitting chip, then flipping the laser emitting chip, finally fixing the laser emitting chip on the circuit board with the gold ball as a sandwich filling bonded on a substrate-pad area of the circuit board.

However, the circuit boards of related art only provide one substrate-pad area. The substrate-pad area is much smaller than the area of the laser emitting chip. During the flip-chip packaging process, the laser emitting chip, supported on the substrate-pad area only through the gold ball, will be prone to tilting or collapsing.

Therefore, it is desirable to provide a laser emitting chip package which can overcome the above-mentioned limitations.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure.

FIG. 1 is an assembled, isometric view of a laser emitting chip package, according to a first exemplary embodiment.

FIG. 2 is an exploded, isometric view of the laser emitting chip package of FIG. 1.

FIG. 3 is an exploded, isometric view of a laser emitting chip package, according to a second exemplary embodiment.

### DETAILED DESCRIPTION

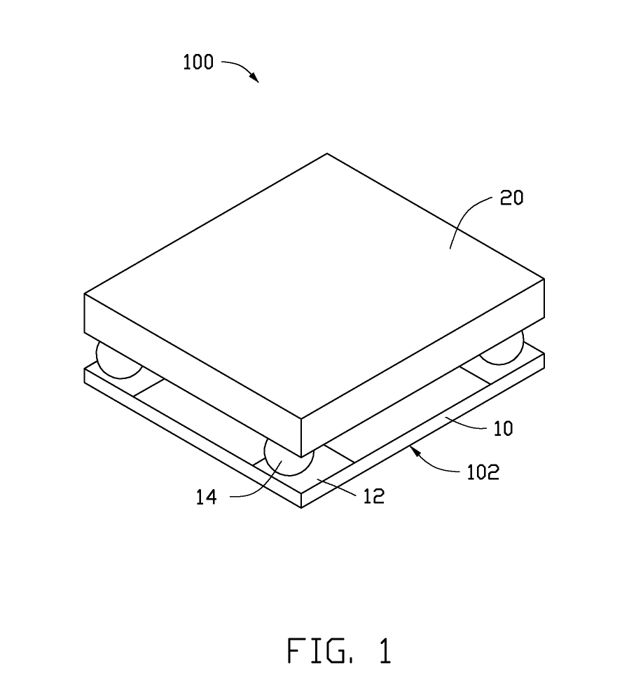

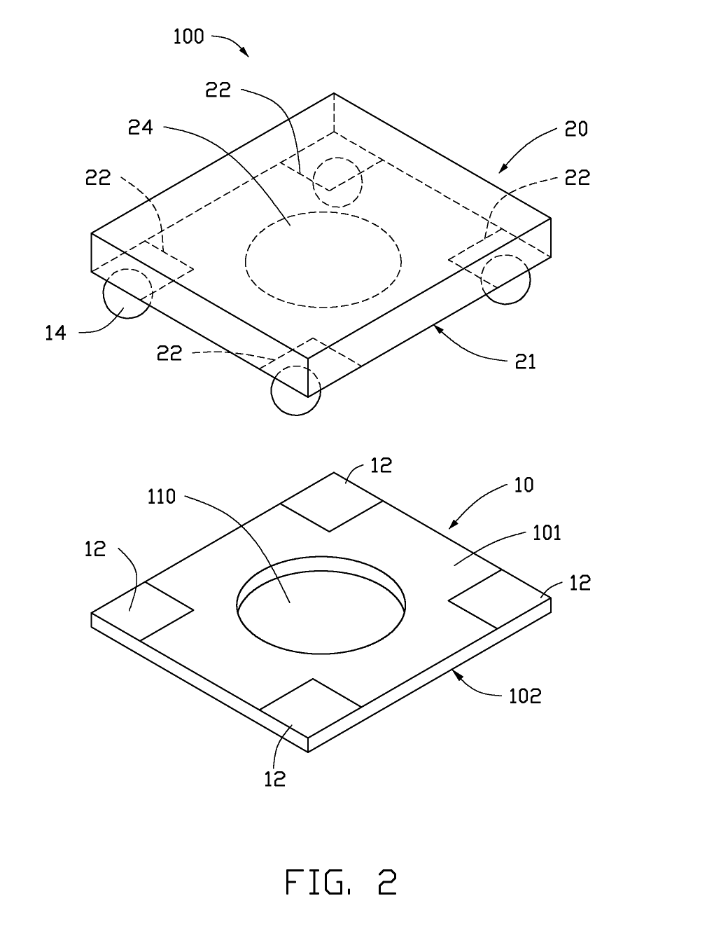

FIGS. 1-2 illustrate a laser emitting chip package 100, according to a first exemplary embodiment. The laser emitting chip package 100 includes a circuit board 10 and a laser emitting chip 20 electrically and mechanically connected to the circuit board 10. The laser emitting chip 20 is configured for emitting laser beams.

The circuit board 10 includes a supporting surface 101 and a bottom surface 102 facing away from the supporting surface 101. In the embodiment, the circuit board 10 is substantially cuboid, and includes four substrate-pad areas 12 respectively formed on the four corners of the supporting surface 101. The circuit board 10 defines a circuit through hole 110 in a center of the supporting surface 101. The through hole 110 passes through both the supporting surface 101 and the bottom surface 102. The four substrate-pad areas 12 surround the through hole 110.

The laser emitting chip 20 includes a first surface 21 opposite to the supporting surface 101 of the circuit board 10. The first surface 21 forms four chip-pad areas 22, and each chip-pad area 22 spatially corresponds to a respective one of the substrate-pad areas 12. A gold ball 14 is explanted on each of the chip-pad areas 22. In other words, the gold balls 14 are in a square arrangement on the chip-pad areas 22. In the embodiment, the four gold balls 14 have essentially identical height. The four gold balls 14 act as supports for the laser emitting chip 20 on the supporting surface 101 of the circuit board 10. The laser emitting chip 20 is electrically connected to the circuit board 10 through the four gold balls 14. The laser emitting chip 20 also includes a laser emitting portion 24 formed on the first surface 21 and aligned with the through hole 110. Laser beams emitted by the laser emitting portion 24 exits through the through hole 110.

Unlike a laser emitting chip package of related art, the laser emitting chip 20 of the laser emitting chip package 100 of the present embodiment is supported on the circuit board 10 through the four gold balls 14 each being connected to a respective one of the four substrate-pad areas 12, and since the four substrate-pad areas 12 are at the corners of the supporting surface 101, this provides a stable platform and prevents the laser emitting chip 20 from tilting or collapsing.

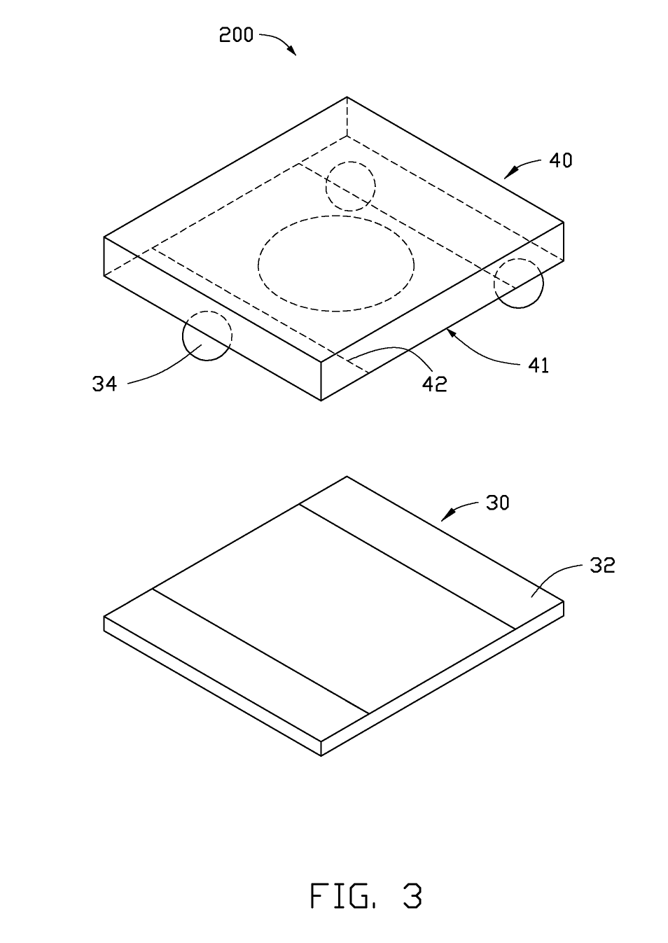

FIG. 3 illustrates a laser emitting chip package 200, in accordance with a second exemplary embodiment. The laser emitting chip package 200 is essentially similar to the laser emitting chip package 100 in the first embodiment, except that the circuit board 30 includes only two substrate-pad areas 32; and the chip pad area 42 utilizes three gold balls 34. In the embodiment, both the two substrate-pad areas 32 are substantially a strip and are opposite to each other. The first surface 41 of the laser emitting chip 20 forms two strip-like chip-pad areas 42 each spatially corresponding to a respective one of the substrate-pad areas 32. One of the three gold balls 34 is explanted on one chip-pad area 42, while the other two gold balls 34 are explanted on the other chip-pad area 42, in other words, the gold balls 34 are in a triangular arrangement on the chip-pad areas 42.

In another embodiment, the four sides of the first surface 41 can have three sides each forming a strip-like chip-pad area 42. At least one gold ball 42 is explanted on each one of the chip-pad areas 42.

It will be understood that the above particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A laser emitting chip package, comprising:
a circuit board comprising at least two substrate-pad areas;
a laser emitting chip comprising at least two chip-pad areas, each of the at least two chip-pad areas spatially corresponding to a respective one of the at least two substrate-pad areas; and
at least three gold balls respectively explanted on the at least two chip-pad areas, the laser emitting chip supported on the circuit board by the at least three gold balls in a triangular or square arrangement between the at least two chip-pad areas and the at least two substrate-pad areas, the laser emitting chip electrically connected to the circuit board also through the at least three gold balls.

2. The laser emitting chip package of claim 1, wherein the circuit board comprises a supporting surface and a bottom surface facing away from the supporting surface, the circuit board is substantially cuboid, and comprises four substrate-pad areas formed on corners of the supporting surface; the number of the at least three gold balls is four; the number of the at least two chip-pad areas is four; each of the at least three gold balls is positioned between and touches a respective one of the at least two substrate-pad areas and a respective one of the at least two chip-pad areas.

3. The laser emitting chip package of claim 2, wherein the circuit board defines a circuit through hole in a center of the supporting surface, the through hole passes through both the supporting surface and the bottom surface, the laser emitting chip also comprises a laser emitting portion formed on its surface opposite to the circuit board and aligned with the through hole.

4. The laser emitting chip package of claim 1, wherein the at least three gold balls have an essentially identical height.

5. The laser emitting chip package of claim 1, wherein the circuit board comprises two strip-like substrate-pad areas, both the two substrate-pad areas are opposite to each other.

6. The laser emitting chip package of claim 5, wherein the laser emitting chip comprises two strip-like chip-pad areas, and each strip-like chip-pad area spatially corresponds to a respective one of the strip-like substrate-pad areas.

7. The laser emitting chip package of claim 6, wherein the at least three gold balls comprises three gold balls, one of the three gold balls is explanted on one of the chip-pad areas, while the other two gold balls are explanted on the other chip-pad area.
